(19) United States
(12) Patent Application Publication
(10) Pub. No.: US 2006/0244020 A1
(43) Pub. Date: Nov. 2, 2006

(54) CMOS image sensors and methods of manufacturing the same

(76) Inventor: Duck-Hyung Lee, Yongin-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/319,603

(22) Filed: Dec. 29, 2005

(30) Foreign Application Priority Data
Apr. 28, 2005 (KR) 10-2005-0035747

(51) Int. Cl. H01L 31/113; H01L 21/00

(52) U.S. Cl. 257/291; 257/292; 257/461; 438/48

(57) ABSTRACT

A CMOS image sensor (CIS) includes an active unit pixel having an Indium-doped impurity layer located below a transfer gate which transfers charges between a photo-receiving element and a floating diffusion region of the active unit pixel.

### BACKGROUND OF THE INVENTION

1. Field of the Invention

The present invention generally relates to image sensors. More particularly, the present invention relates to image sensors configured to reduce dark current and to methods of manufacturing images sensors to reduce dark current.

2. Description of the Related Art.

Certain types of image sensors utilize photo-receiving elements (such as photo-diodes) to capture incident light and convert the light to an electric charge capable of image processing. Examples include Complimentary Metal Oxide Semiconductor (CMOS) image sensors (CIS). CIS devices are generally characterized by an array of photo-receiving elements (active unit pixels) having access devices (e.g., transistors) for connection to word lines and bit lines. The configuration of the CIS device is generally analogous to that of a CMOS memory device.

Each active unit pixel of a CIS device typically includes a transfer transistor for transferring charges accumulated in the photo-receiving element to a floating diffusion region. The charges transferred to floating diffusion region are used to drive the gate of a source follower transistor which generates an output voltage representative of pixel data.

As CIS devices become highly integrated, the width and length dimensions of the gate of the transfer transistor have been reduced. The result has been the formation of a voltage-transfer bottleneck in which charges are not fully transferred from the photo-receiving element to the floating diffusion region. The result can be increased dark current and degraded image sensing quality of the CIS device.

There is a general demand in the industry for image sensors which exhibit improved charge transfer characteristics from the photo-receiving element to a floating diffusion region of each active pixel unit of the image sensors.

### SUMMARY OF THE INVENTION

According to one aspect of the present invention, a CMOS image sensor (CIS) is provided which includes an active unit pixel including an Indium-doped layer located below a transfer gate which transfers charges between a photo-receiving element and a floating diffusion region of the active unit pixel.

According to another aspect of the present invention, a CMOS image sensor (CIS) is provided which includes an active unit pixel including at least one p-doped well and a p-doped layer located below a transfer gate which transfers charges between a photo-receiving element and a floating diffusion region of the active unit pixel, where a diffusion coefficient of the p-doped layer is less than a diffusion coefficient of the p-doped well.

According to still another aspect of the present invention, a CMOS image sensor (CIS) is provided which includes a photo-receiving element, a reset transistor electrically connected to the photo-receiving element, a transfer transistor electrically connected between the photo-receiving element and the reset transistor, and a drive transistor including a gate electrically connected to a floating diffusion region. The transfer transistor includes an indium-doped layer and transfer charges from the photo-receiving element to the floating diffusion region.

According to yet another aspect of the present invention, a method of fabricating an active unit pixel of a CMOS image sensor is provided which includes implanting Indium into a surface of a substrate to form a Indium-doped impurity layer, and forming a transfer gate over the Indium-doped impurity layer and a between a photo-receiving element and a floating diffusion region of the substrate.

### BRIEF DESCRIPTION OF THE DRAWINGS

The above and other aspects and features of the present invention will become readily apparent from the detailed description that follows, with reference to the accompanying drawings, in which:

FIG. 1 is a schematic block diagram of a Complimentary Metal Oxide Semiconductor (CMOS) image sensor (CIS);

FIG. 2 is an equivalent circuit diagram of an active unit pixel element of the CIS device of FIG. 1;

FIG. 3 is a diagram illustrating a top view layout of the active unit pixel element of FIG. 2 according to an embodiment of the present invention;

FIG. 4 is a cross-sectional view taken along line IV-IV′ of the active unit pixel element of FIG. 3 according to an embodiment of the present invention;

FIGS. 5 and 6 are a graph and a table, respectively, for comparing diffusion characteristics of Boron and Indium impurities;

FIGS. 7 and 8 are graphs for comparing potential barriers resulting from the use of Boron and Indium impurities beneath the transfer gate of an active unit pixel;

FIGS. 9, 10, 11, 12 and 13 are cross-sectional views taken along line IV-IV′ of the active unit pixel element of FIG. 3 according to respective other embodiments of the present invention;

FIGS. 14A through 14F are cross-sectional views for use in explaining a method of fabricating the active unit pixel illustrated in FIG. 4 according to an embodiment of the present invention;

FIGS. 15A through 15C are cross-sectional views for use in explaining a method of fabricating the active unit pixel illustrated in FIG. 9 according to an embodiment of the present invention;

FIGS. 16A and 16B are cross-sectional views for use in explaining a method of fabricating the active unit pixel illustrated in FIG. 10 according to an embodiment of the present invention;

FIGS. 17 is cross-sectional view for use in explaining a method of fabricating the active unit pixel illustrated in FIG. 11 according to an embodiment of the present invention; and

FIG. 18 is a block diagram of a processor-based system employing an image sensor having an active unit pixel according to embodiments of the present invention.

### DETAILED DESCRIPTION OF PREFERRED EMBODIMENTS

The present invention will now be described by way of several preferred but non-limiting embodiments. Throughout the drawings, like elements are referred to by like reference numbers.

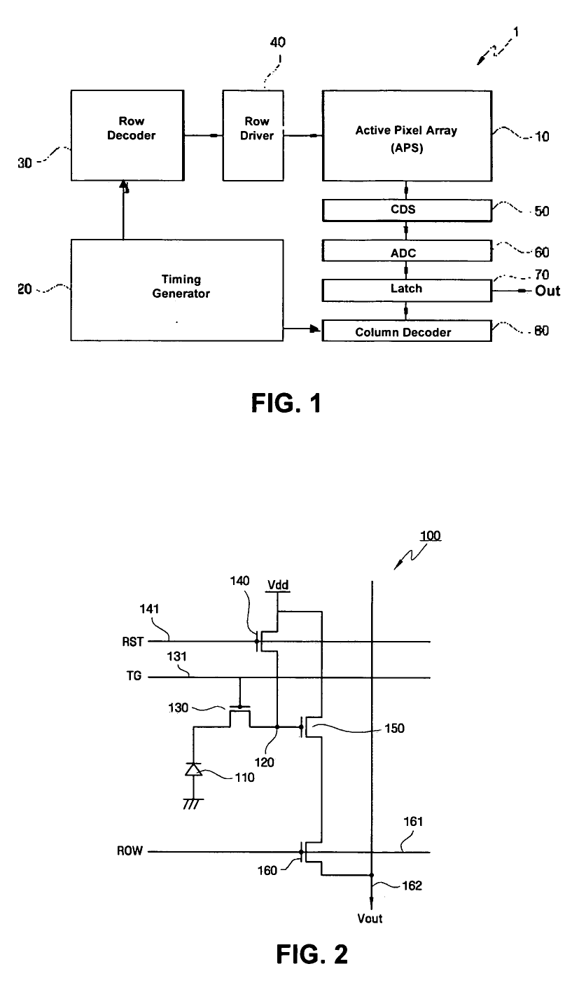

FIG. 1 is a block diagram of an example of a CMOS image sensor (CIS) 1. The CMOS image sensor 1 generally includes an active pixel sensor (APS) array 10, a timing generator 20, a row decoder 30, a row driver 40, a correlated double sampling and digital converting (CDS) circuit 50, an analog to digital converter (ADC) 60, a latch circuit 70, and a column decoder 80. The APS array 10 contains a plurality of active unit pixels arranged in rows and columns. Those of ordinary skill are well-acquainted with the operation of the CIS 1 represented in FIG. 1, and a detailed description thereof is therefore omitted here. Generally, however, the timing generator 20 controls the operational timing of the row decoder 30 and column decoder 80. The row driver 40 is responsive to the row decoder 30 to selectively activate rows of the active pixel array 10. The CDS 50 and ADC 60 are responsive to the column decoder 80 and latch circuit 70 to sample and output column voltages of the active pixel array 10. In this example, image data is output from the latch circuit 70.

An equivalent circuit diagram of a non-limiting example of an active unit pixel 100 of the APS array 10 (FIG. 1) is shown in FIG. 2. A photo-receiving element 110 (e.g., a photo-diode) of the active unit pixel 100 captures incident light and converts the captured light into an electric charge. The electric charge is selectively transferred from the photodiode 110 to a floating diffusion region 120 via a transfer transistor 130. The transfer transistor 130 is controlled by a transfer gate TG signal supplied to line 131. The floating diffusion region 120 is connected to the gate of a drive transistor 150 which functions as a source follower (amplifier) for buffering an output voltage. The output voltage is selectively transferred as an output voltage Vout to an output line 162 by a select transistor 160. The select transistor 160 is controlled by a row select signal ROW applied to line 161. Finally, a reset transistor 140 is controlled by a reset signal RST applied to line 141 to selectively reset charges accumulated in the floating diffusion region 120 to a reference level Vdd.

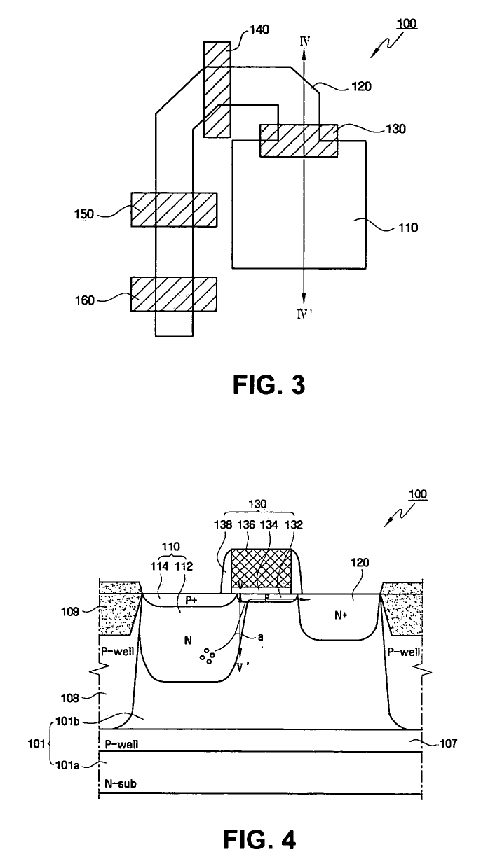

FIG. 3 illustrates a top-view layout of the active unit pixel 100 depicted in FIG. 2, and FIG. 4 is a cross-sectional view taken along line IV-IV′ of FIG. 3.

Referring first to FIG. 3, a plurality of gate structures 130, 140, 150 and 160 are located over an active region as shown. The gate structures 130, 140, 150 and 160 respectively correspond to the transfer transistor 130, the reset transistor 140, the drive transistor 150, and the select transistor 160 illustrated in FIG. 2. The active region includes a photo-receiving element 110 which corresponds to the photo-receiving element 110 of FIG. 2, and a floating diffusion region 120 which corresponds to the floating diffusion region 120 of FIG. 2.

Turning now to FIG. 4, the substrate 101 of the image pixel 100 is formed of an n-type semiconductor substrate 101a and an n-type epitaxial layer 101b having a p-type deep well 107 interposed there between. An active region of the substrate 100 is defined between field oxide regions 109, and p-type isolation wells 108 extend below the field oxide regions 109 to a depth of the p-type deep well 107. An impurity of the p-type isolation wells 109 may, for example, be one or both of Boron difluoride (BF₂) and Boron.

In this example, the photo-receiving element 110 is a photo-diode defined by an n-type photodiode region 112 and a p⁺-type pinning layer 114. An n⁺-type floating diffusion region 120 is spaced from the photo-receiving element 110, and a transfer gate 103 is positioned there between as illustrated in FIGS. 3 and 4.

The transfer gate 130 is generally defined by a gate electrode 136, a gate dielectric layer 134, and gate insulating spacers (or sidewalls) 138.

In operation, negative charges “a” accumulated in the photo-diode region 112 when light is incident on the surface of the active unit pixel 100. The charges are selectively transferred to the floating diffusion region 120 by operation of the transfer gate 130.

As CIS devices become highly integrated, the width and length dimensions of the transfer gate 130 have been reduced. The result has been the formation of a voltage-transfer bottleneck in which charges are not fully transferred from the photo-diode region 112 to the floating diffusion region 120. Image sensing quality is degraded as accumulated charges remain in the photo-diode region 112.

To overcome some of the problems associated with the small dimensions of the transfer gate 130, it is known to implant specific types of impurities (p-type and/or n-type) beneath the transfer gate 130 in an effort to control the potential barrier characteristics of the channel region. In particular, boron (B) and phosphorous (P) have been implanted under the transfer gate in an effort to reduce kTc noise and to control the threshold voltage of the transfer gate.

Unexpectedly, however, the present inventors have discovered that indium (In) achieves superior results to previously utilized impurities when implanted beneath the transfer gate of the active unit pixel of a CIS device. This is particularly surprising since Indium is generally thought of as unstable when compared, for example, to boron as a semiconductor dopant. Operational differences between the use of Indium and Boron will be presented later herein.

Returning to FIG. 4, an Indium-doped p-type layer 132 is located below the transfer gate 130 and extends between the photo-receiving element 110 and the floating diffusion region 120. Also, although not shown, an additional n⁺-type layer may be located within channel region beneath the Indium-doped p-type layer 132.

As examples, a dopant concentration of the photo-diode region 112 may be in a range of E15 to E18 atoms/cm³; a dopant concentration of the pinning layer 114 may be in a range of E17 to E20 atoms/cm³; and a dopant concentration of the Indium-doped p-type layer 132 may be in a range of E16 to E19 atoms/cm³.

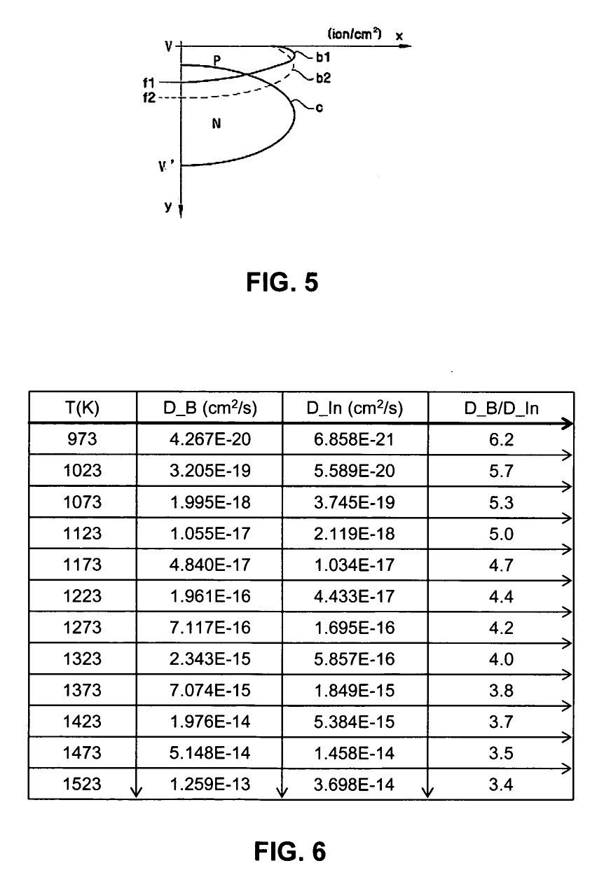

The operational advantages of using Indium in favor the conventional use of Boron will now be explained with reference to FIGS. 5-8.

FIG. 5 is a graph illustrating doping profiles taken alone line V-V′ of FIG. 4. As shown in FIG. 4, line V-V′ intersects the n-type photo-diode region 112 and the p-type layer 132. The x-axis of FIG. 5 denotes impurity concentration, while the y-axis denotes the depth from the substrate surface. In particular, line b1 illustrates the dopant profile in the case where the p-type layer 132 is implanted with Indium, and line b2 illustrates the dopant profile in the case where Boron is implanted under like conditions. Line c is illustrative of the dopant profile of the n-type dopant (e.g., Phosphorus) of the n-type photo-diode region 112.

As illustrated in FIG. 5, the dopant profile of Boron (b2) extends to a greater depth f2 then the depth f1 of the dopant profile of Indium (b1). Without intending to limit the invention, this disparity in the depths f1 and f2 can be explained by the differing diffusion coefficients of Boron and Indium. The diffusion coefficient of an impurity is defined here as the rate (in cm²/sec) at which the impurity diffuses into a substrate at a given temperature. The table of FIG. 6 comparatively illustrates the diffusion coefficients of Boron and Indium. In particular, the first column of FIG. 6 shows the diffusion temperature T(K) in degrees Kelvin. The second and third columns of FIG. 6 show the diffusion coefficients of Boron (D_B) and Indium (D_In), respectively, at each of the given temperatures. The final column of FIG. 6 shows the ratio (D_B/D_In) of the diffusion coefficients of Boron (D_B) and Indium (D_In). As shown in the table, depending on temperature, the diffusion coefficient of Boron is about 3.4 to 6.2 times greater than that of Indium.

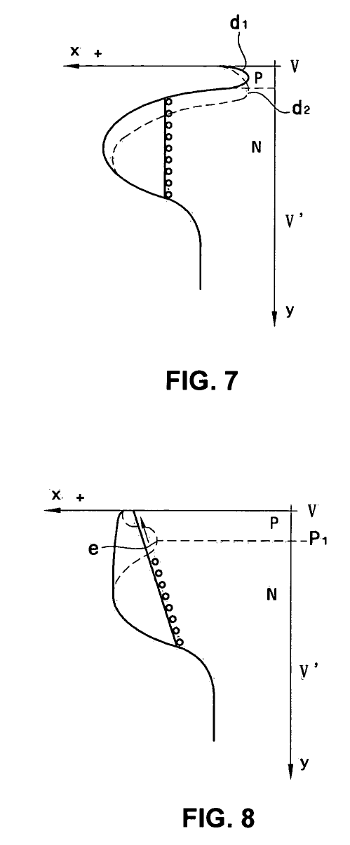

Since the diffusion coefficient of Boron exceeds that of Indium, Boron will diffuse deeper into the substrate when the device is subjected to various thermal treatments during fabrication (e.g., when forming the gate dielectric layer 134 of the transfer gate 130). This result is illustrated in FIG. 5 where the peak concentration of Indium (b1) is located closer to the substrate surface than that of Boron (b2). As is explained next with reference to FIGS. 7 and 8, the use of Indium thus advantageously results in the potential barrier within the channel region being located closer to the substrate surface.

FIGS. 7 and 8 illustrate the potential barrier along the line V-V′ of FIG. 4 in the cases where the transfer gate is OFF and ON, respectively. The ON state is achieved by application of 2.8 volts to the transfer gate. The small circles in the figures are intended to represent charges accumulated in the n-region of the photo-receiving element. The dashed line d2 of these figures illustrates the case where Boron is implanted beneath the transfer gate, and the solid line d1 illustrates the case where Indium is implanted beneath the transfer gate. The use of Indium impurities beneath the transfer gate of an active unit pixel brings the peak impurity concentration closer to the substrate surface. As a result, and as shown in FIGS. 7 and 8, the potential barrier within the channel of the transfer gate is also brought closer to the service, thus improving the charge transfer characteristics of the active unit pixel. Reference character “e” (at depth P1) of FIG. 8 represents a bottleneck in the transfer of charges from n-region of the photo-receiving element in the case of Boron impurities. No such bottleneck is present in the case of Indium impurities (when, as mentioned above, about 2.8 volts is applied to the transfer gate).

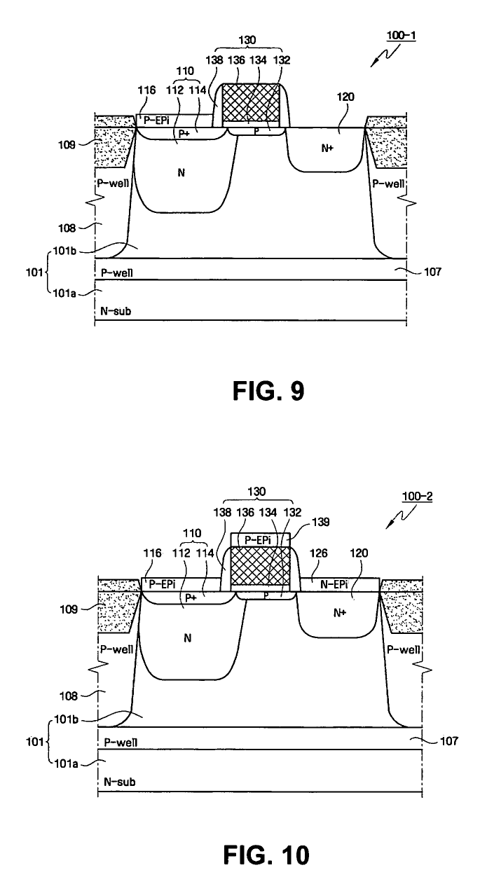

FIG. 9 illustrates another embodiment of an active unit pixel 100-1 of the present invention. This embodiment differs from that of FIG. 4 in that a raised pinning layer 116 is provided over the pinning layer 114. The raised pinning layer 116 is a p-type epitaxial layer that is effective in suppressing dark current and reducing image lag. In this example, the raised pinning layer 116 has a thickness of approximately 300 to 1500 Å and an impurity concentration of about E17 to E20 atoms/cm³. The p-type impurities of the raised pinning layer 116 may, for example, be one or more of BF₂, Boron or Indium. It is noted that the impurities of the p-type layer 132 of this embodiment may also be formed of one or more of BF₂, Boron or Indium, although Indium is preferred for the same reasons as the first described embodiment.

The remaining elements of FIG. 9 are the same as the identically number elements of FIG. 4, and accordingly, a detailed description thereof is omitted here to avoid redundancy.

FIG. 10 illustrates another embodiment of an active unit pixel 100-2 of the present invention. This embodiment differs from that of FIG. 4 in that the raised pinning layer 116 is provided over the pinning layer 114, an epitaxial layer 126 is provided on the floating diffusion region 120, and an epitaxial gate layer 139 is provided on the transfer gate 130. The raised pinning layer 116 is a p-type epitaxial layer with the same characteristics as the raise pinning layer 116 of previously described FIG. 9. Like the embodiment of FIG. 9, the impurities of the p-type layer 132 of this embodiment may also be formed of one or more of BF₂, Boron or Indium, although Indium is preferred for the same reasons as the first described embodiment. The epitaxial layer 126 is an n-type epitaxial layer which can improve contact characteristics with the floating diffusion region 120. In this example, the raised pinning layer 116 has a thickness of approximately 300 to 1500 Å and an impurity concentration of about E17 to E20 atoms/cm³. The epitaxial gate layer is considered optional in the context of the present embodiment, and can be either an n-type or p-type epitaxial layer.

The remaining elements of FIG. 10 are the same as the identically numbered elements of FIG. 4, and accordingly, a detailed description thereof is omitted here to avoid redundancy.

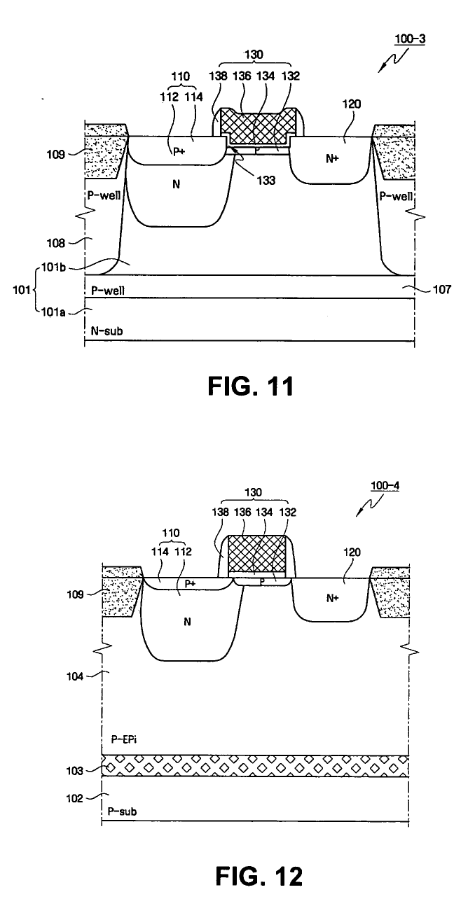

FIG. 11 illustrates yet another embodiment of an active unit pixel 100-3 of the present invention. This embodiment differs from that of FIG. 4 in that the transfer gate 130 is a recessed transferred gate which can be effective in reducing image lag. That is, as illustrated in FIG. 11, a portion of the transfer gate 130 extends to a depth within a recess of substrate surface. Here, like the embodiment of FIG. 4, the p-type layer 132 is an Indium doped layer which may have a dopant concentration in the range of E16 to E19 atoms/cm³.

The remaining elements of FIG. 11 are the same as the identically numbered elements of FIG. 4, and accordingly, a detailed description thereof is omitted here to avoid redundancy.

FIG. 12 illustrates still another embodiment of an active unit pixel 100-4 of the present invention. This embodiment differs from that of FIG. 4 in that the substrate structure of FIG. 4 is replaced with a p-type substrate 102, a high-density p-doped gathering layer 103, and a p-type epitaxial layer 104. The gathering layer 103, which is effective in reducing dark current, is formed by implanting group IV family atoms (such as carbon or germanium) at a concentration of E18 to E21 atoms/cm³. Here, like the embodiment of FIG. 4, the p-type layer 132 is an Indium doped layer which may have a dopant concentration in the range of about E16 to E19 atoms/cm³. The high-density doped gathering layer 103 inhibits cross-talk and reduces noise among pixels of the image sensor. The p-type epitaxial layer 104 provides a higher saturation of the photo-receiving element 104 than that of an n-type layer.

The remaining elements of FIG. 12 are the same as the identically numbered elements of FIG. 4, and accordingly, a detailed description thereof is omitted here to avoid redundancy.

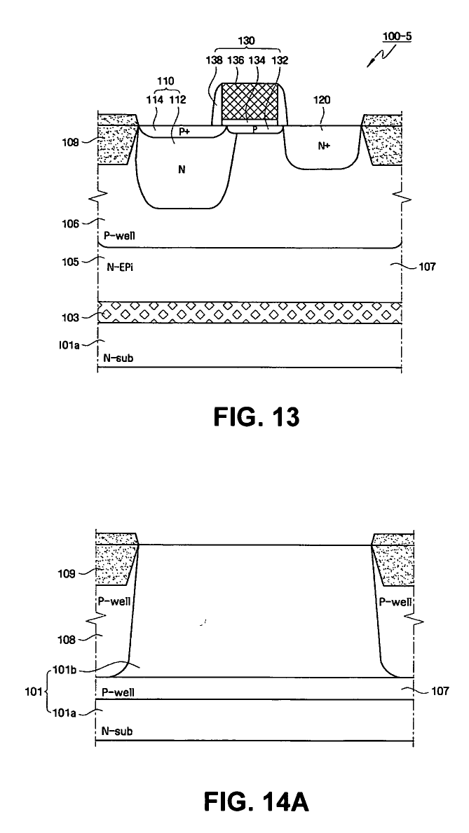

FIG. 13 illustrates another embodiment of an active unit pixel 100-5 of the present invention. This embodiment differs from that of FIG. 4 in that the substrate structure of FIG. 4 is replaced with an n-type substrate 101a, a high-density p-doped gathering layer 103, and an n-type epitaxial layer 105. In addition, a p-type well 106 is formed in the surface of the substrate. The gathering layer 103 may be formed in the same manner as described previously in connection with FIG. 12. Here, like the embodiment of FIG. 4, the p-type layer 132 is an Indium doped layer which may have a dopant concentration in the range of E16 to E19 atoms/cm³. The n-type substrate 101a and the n-type epitaxial layer 105 provide improved cross-talk characteristics when compared to the n-type epitaxial layer and p-type substrate of FIG. 12.

The remaining elements of FIG. 13 are the same as the identically numbered elements of FIG. 4, and accordingly, a detailed description thereof is omitted here to avoid redundancy.

The embodiments of FIGS. 4 and 9-13 are presented to illustrate that the present invention can be implemented in a variety of different configurations. As one skilled in the art will appreciate, other structures are possible, and accordingly, the invention is not limited to these particular configurations of FIGS. 4 and 9-13.

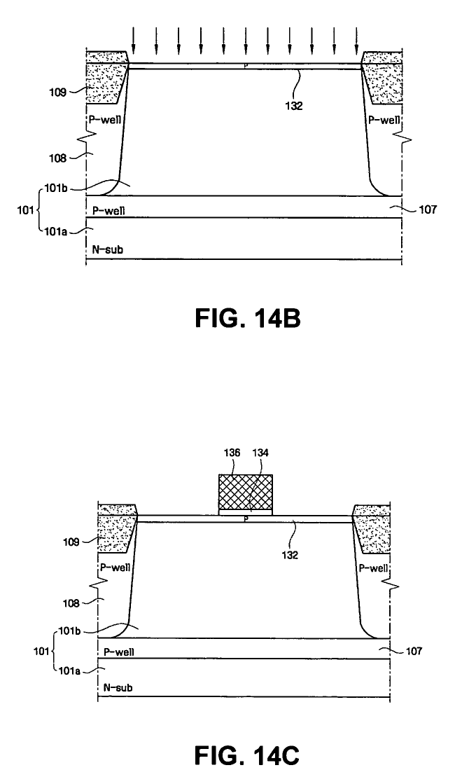

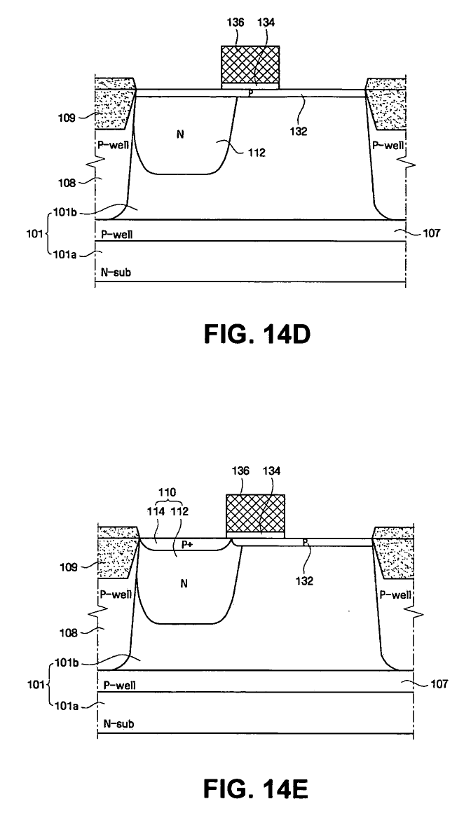

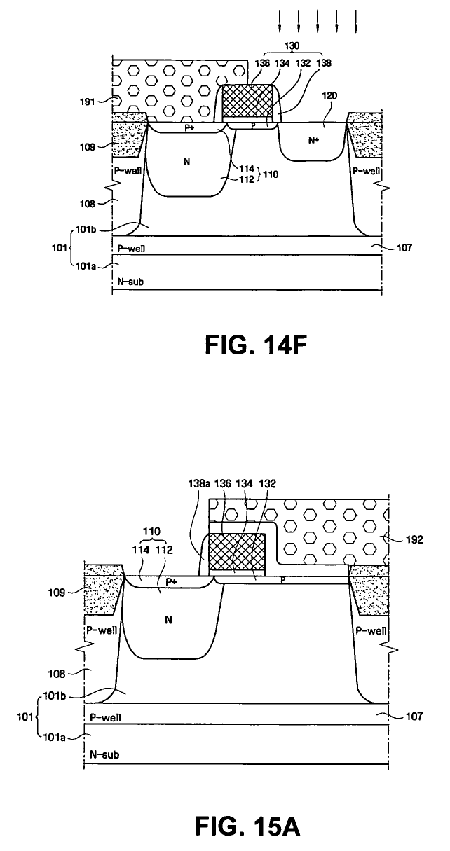

An exemplary method of fabricating the active unit pixel 100 of FIG. 4 will now be described with reference to FIGS. 14A through 14F.

Referring first to FIG. 14A, field regions 109 are formed to define an active region in a semiconductor substrate 101. The substrate 101 includes an n-type epitaxial layer 101b formed over an n-type substrate 101a. A deep p-type well 107 is formed by implanting p-type dopants such as Boron at an energy of approximately 2 Meg eV and at a dosage of about E10 to E16 atoms/cm². The concentration of the deep well 107 is approximately E15 to E20 atoms/cm³. An isolation p-type well 108 is also formed by implanting p-type ions to achieve a concentration of about E16 to E18 atoms/cm³. The isolation p-type well 108 preferably contacts the deep p-type well 107 in order to minimize crosstalk among adjacent active unit pixels.

Next, referring to FIG. 14B, Indium is implanted as p-type dopants in the surface of the substrate 101. Implantation conditions may be at an energy of approximately 50 to 100 K eV and at a dosage of about E11 to E13 atoms/cm². As a result, an indium doped p-type impurity layer 132 is formed at a depth of approximately 2000 Å and at a concentration of approximately E16 to E19 atoms/cm³.

Referring now to FIG. 14C, a gate dielectric layer 134 and a gate electrode 136 are patterned over the p-type impurity layer 132 using known processes. Formation of the gate dielectric layer 134 generally includes a dry or wet oxidation process at the temperature of approximately 800 to 1000° C. As explained previously, the low diffusion coefficient of the indium doped impurity layer 132 will result in less diffusion of dopants than if the impurity layer 132 contained Boron dopants.

Next, referring to FIG. 14D, an n-type well is formed using a conventional ion implantation process to define the photo-diode region 112.

Referring to FIG. 14E, a pinning layer 114 is formed in the photo-diode region 112 using conventional implantation processes. In this manner, the photo receiving element 110 is formed. The pinning layer can be formed, for example, by implantation of Boron or Indium.

Referring to FIG. 14F, the sidewall spacers 138 are formed on sidewalls of the gate electrode 136 and the gate dielectric layer 134 using known techniques. Then, the floating diffusion layer 120 is formed by patterning a photoresist layer 191 to mask the photo receiving element 110, and by then implanting n-type dopants such as Boron into the substrate 101. The photoresist layer 191 is then removed and a device corresponding to the embodiment of FIG. 4 is obtained.

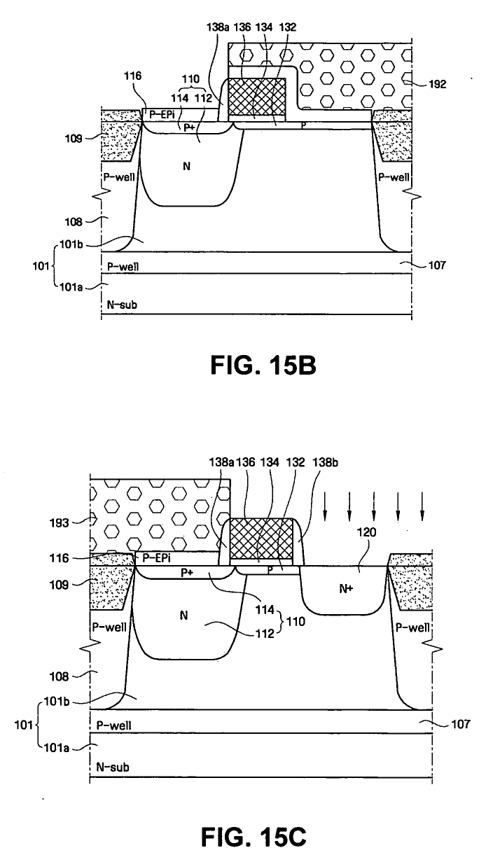

An exemplary method of fabricating the active unit pixel 100-1 of FIG. 9 will now be explained with reference to FIGS. 15A through 15C.

Referring first to FIG. 15A, a structure is illustrated which is similar to that obtained in previously described FIG. 14E. In FIG. 15A, however, one of sidewall spacers 138a has been formed by conventional chemical vapor deposition (CVD) and lithography processes. The gate spacer 138a is formed of a dielectric material such as silicon dioxide by using a photoresist layer 192 as a mask.

Next, referring to FIG. 15B, the raise pinning layer 116 is formed to a thickness of approximately 300 to 1500 Å by conventional expitaxial growth processes. As discussed previously, the raise pinning layer 116 is effective in suppressing dark current and reducing image lag. P-type impurities are then implanted to obtain an impurity concentration of about E17 to E20 atoms/cm³. The p-type impurities of the raised pinning layer 116 may, for example, be one or more of BF₂, Boron or Indium. It is also noted that the impurities of the p-type layer 132 of this embodiment may also be formed of one or more of BF₂, Boron or Indium, although Indium is preferred for the same reasons as the first described embodiment.

Next, referring to FIG. 15C, the photoresist pattern 192 (FIG. 15B) is removed and another photoresist pattern 193 is formed to cover the substrate region containing the photo-receiving element 110. In addition, the other sidewall spacer 138b is formed by conventional etching techniques. The n⁺-type floating diffusion region 120 is then formed in the same manner as described previously in connection with FIG. 14F. The photoresist layer 193 is then removed and a device corresponding to the embodiment of FIG. 9 is obtained.

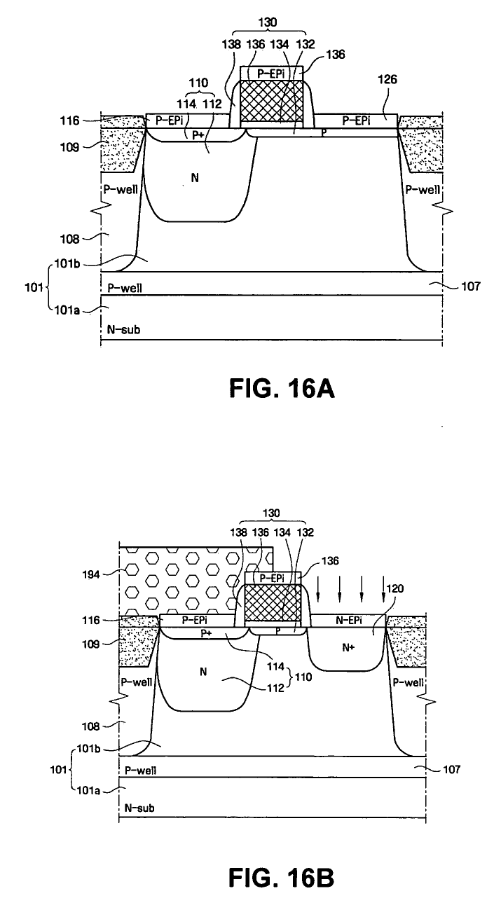

An exemplary method of fabricating the active unit pixel 100-2 of FIG. 10 will now be explained with reference to FIGS. 16A and 16B.

The structure illustrated in FIG. 16A is similar to that of FIG. 14E, except that the structure of FIG. 16A includes the formation of the sidewall spacers 138. In addition, FIG. 16A illustrates a plurality of p-type expitaxial layers 116, 136 and 126 that have been formed using conventional techniques over the active region of the substrate 101.

Referring next to FIG. 16B, a photoresist pattern 194 is formed to mask the region of the substrate containing the photo-receiving element 110. Ion implantation of n-type impurities is then carried out to define the floating diffusion region 120 and make the epitaxial layer 126 (FIG. 16A) an n-type epitaxial layer. The photoresist layer 194 is then removed and a device corresponding to the embodiment of FIG. 10 is obtained.

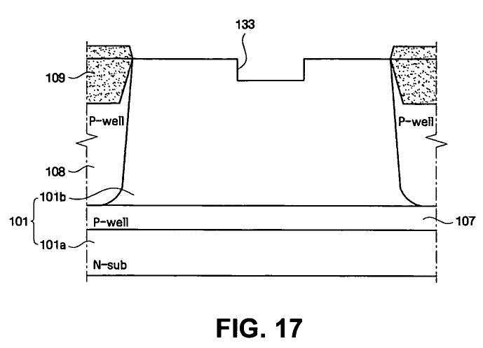

For completeness, FIG. 17 is presented to explain an exemplary method of fabricating the active unit pixel illustrated in FIG. 11. As shown in FIG. 17, a recess 133 is formed in the substrate surface of a structure which is otherwise similar to that shown in FIG. 14A. The remaining process steps are similar to those discussed previously in connection with FIGS. 14B through 14F, and accordingly, these process steps are not repeated here to avoid redundancy.

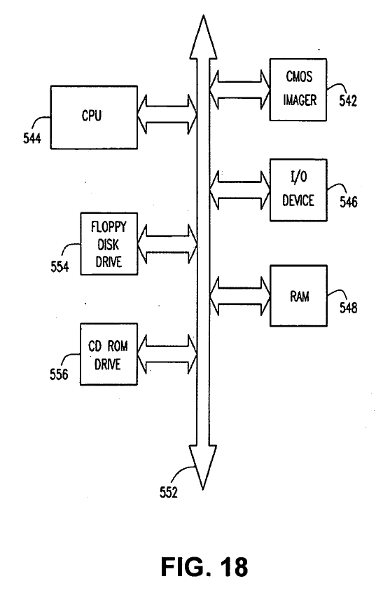

FIG. 18 illustrates an exemplary processor-based system having a CMOS imager device 542, where the CMOS imager device 542 includes an image sensor containing active unit pixels in accordance with the above-described embodiments of the present invention. The processor-based system is exemplary of a system receiving the output of a CMOS imager device. Without being limiting, such a system could include a computer system, camera system, scanner, machine vision system, vehicle navigation system, video phone, surveillance system, auto focus system, star tracker system, motion detection system, image stabilization system, mobile phone, all of which can utilize the present invention.

Referring to FIG. 18, the processor-based system of this example generally includes a central processing unit (CPU) 544, for example, a microprocessor, that communicates with an input/output (I/O) device 546 over a bus 552. The CMOS imager device 542 produces an output image from signals supplied from an active pixel array of an image sensor, and also communicates with the system over bus 552 or other communication link. The system may also include random access memory (RAM) 548, and, in the case of a computer system may include peripheral devices such as a flash-memory card slot 554 and a display 556 which also communicate with the CPU 544 over the bus 552. It may also be desirable to integrate the processor 544, CMOS imager device 542 and memory 548 on a single integrated circuit (IC) chip.

As described above, the use of Indium impurities beneath the transfer gate of an active unit pixel advantageously brings the peak impurity concentration closer to the substrate surface. As a result, the potential barrier within the channel of the transfer gate is also brought closer to the service, which improves the charge transfer characteristics of the active unit pixel.

It should be noted, however, that the invention is not limited to Indium as the impurities implanted beneath the transfer gate. Rather, Indium has been emphasized herein because of its low diffusion coefficient. Other p-type impurities having low diffusion coefficients may instead be suitable. The invention thus encompasses, for example, a device having p-wells formed of a first p-type impurity having a first diffusion coefficient, and a p-type impurity layer formed beneath the transfer gate having second impurities of a second diffusion coefficient which is less than the first diffusion coefficient.

In addition, it should be noted that the invention is not limited to photo-receiving elements composed of p-type pinning layers formed on n-type photo-diode layers. Other types of photo-receiving elements, such as photo-gates, may instead be utilized.

Although the present invention has been described above in connection with the preferred embodiments thereof, the present invention is not so limited. Rather, various changes to and modifications of the preferred embodiments will become readily apparent to those of ordinary skill in the art. Accordingly, the present invention is not limited to the preferred embodiments described above. Rather, the true spirit and scope of the invention is defined by the accompanying claims.

What is claimed is:

1. A CMOS image sensor (CIS) comprising an active unit pixel including an Indium-doped layer located below a transfer gate which transfers charges between a photo-receiving element and a floating diffusion region of the active unit pixel.

2. The CIS of claim 1, wherein an Indium concentration of the impurity layer is about 1*10¹⁵/cm³ to about 1*10¹⁹/cm³.

3. The CIS of claim 1, wherein the photo-receiving element comprises an n-type photo-diode region and a p-type pinning layer located at a surface region of the substrate and over said photo-diode region.

4. The CIS of claim 3, wherein the transfer gate comprises gate dielectric layer located at the surface of the substrate, a gate electrode located over the gate dielectric layer, and first and second sidewall spacers.

5. The CIS of claim 3, wherein a top surface of the pinning layer is higher than a top surface of the substrate.

6. The CIS of claim 5, wherein pinning layer comprises a first portion formed in the top surface of the substrate, and a second portion located on the top surface of the first portion.

7. The CIS of claim 3, wherein a top surface of the floating diffusion region is higher than the top surface of the substrate.

8. The CIS of claim 7, wherein the floating diffusion region comprises a first portion formed in a top surface of the substrate, and a second portion located on the top surface of the first portion.

9. The CIS of claim 4, wherein the gate electrode and the gate dielectric layer are partially located within a recess in the surface of the substrate.

10. The CIS of claim 1, further comprising at least one p-type doped isolation well in the substrate.

11. The CIS of claim 10, wherein an impurity of the p-type doped isolation well is different from Indium.

12. The CIS of claim 10, wherein an impurity of the p-type doped isolation well is one or both of Boron difluoride and Boron.

13. The CIS of claim 10, further comprising a buried p-type doped region located at a depth within the substrate and contacting the at least one p-type doped isolation well.

14. The CIS of claim 1, further comprising a buried gathering layer located at a depth within the substrate, wherein the gathering layer comprises group-IV family atoms.

15. A CMOS image sensor (CIS) comprising an active unit pixel including at least one p-doped well and a p-doped layer located below a transfer gate which transfers charges between a photo-receiving element and a floating diffusion region of the active unit pixel, wherein a diffusion coefficient of dopants in the p-doped layer is less than a diffusion coefficient of dopants in the p-doped well.

16. The CIS of claim 15, wherein the p-doped layer is an Indium-doped layer.

17. The CIS of claim 16, wherein the p-doped well is a Boron-doped well.

18. The CIS of claim 17, wherein an Indium concentration of the impurity layer is about 1*10¹⁵/cm³ to about 1*10¹⁹/cm³.

19. The CIS of claim 16, wherein the transfer gate is recessed in a surface of the substrate.

20. The CIS of claim 19, wherein the substrate is an n-type semiconductor substrate having a p-type epitaxial layer.

21. A CMOS image sensor (CIS), comprising:
a photo-receiving element;
a reset transistor electrically connected to the photo-receiving element;
a transfer transistor, electrically connected between the photo-receiving element and the reset transistor, which includes an indium-doped layer and which transfer charges from the photo-receiving element to a floating diffusion region; and
a drive transistor including a gate electrically connected to the floating diffusion region.

22. The CIS of claim 22, wherein the reset transistor and the drive transistor each include a terminal which is electrically connected to a voltage source.

23. The CIS of claim 22, wherein the drive transistor is electrically connected to a select transistor.

24. A method of fabricating an active unit pixel of a CMOS image sensor comprising implanting Indium into a surface of a substrate to form a Indium-doped impurity layer, and forming a transfer gate over the Indium-doped impurity layer and a between a photo-receiving element and a floating diffusion region of the substrate.

25. The method of claim 24, wherein an Indium concentration of the impurity layer is about 1*10¹⁵/cm³ to about 1*10¹⁹/cm³.
